(19) United States
(12) Patent Application Publication
(10) Pub. No.: US 2019/0292092 A1
(43) Pub. Date: Sep. 26, 2019

(54) COMPOSITION FOR FORMING SOLAR CELL ELECTRODE AND ELECTRODE PREPARED USING THE SAME

(71) Applicant: SAMSUNG SDI CO., LTD., Yongin-si (KR)

(72) Inventors: Ji Seon LEE, Suwon-si (KR); Min Su PARK, Suwon-si (KR); Sang Hee PARK, Suwon-si (KR)

(21) Appl. No.: 16/174,469

(22) Filed: Oct. 30, 2018

(30) Foreign Application Priority Data
Mar. 26, 2018 (KR) 10-2018-0034664

(51) Int. Cl. C03C 8/18; H01L 31/0224; C03C 8/02

(52) U.S. Cl. CPC C03C 8/18; H01L 31/022425; C03C 2204/00; C03C 2205/00; C03C 8/02

(57) ABSTRACT

A composition for solar cell electrodes and a solar cell electrode fabricated using the composition, the composition including a conductive powder; a glass frit; and an organic vehicle, wherein the glass frit has a reaction index (RI) of about 0.5 to about 1.0, as calculated according to Equation 1:

Reaction index (RI)=Ib/Ia <Equation 1>
wherein, in Equation 1, Ia denotes a maximum peak intensity measured on a specimen at 20.5° to 20.7° (2θ) by XRD analysis, the specimen being obtained by mixing the glass frit with Si₃N₄ powder in a weight ratio of 1:1 to prepare pellets, followed by heat-treatment at 800° C. for 10 minutes, and Ib denotes a maximum peak intensity measured on the specimen at 20.75° to 20.95° (2θ) by XRD analysis.

### CROSS-REFERENCE TO RELATED APPLICATION

Korean Patent Application No. 10-2018-0034664, filed on Mar. 26, 2018, in the Korean Intellectual Property Office, and entitled: “Composition for Forming Solar Cell Electrode and Electrode Prepared Using the Same,” is incorporated by reference herein in its entirety.

### BACKGROUND

### 1. Field

Embodiments relate to a composition for solar cell electrodes and a solar cell electrode fabricated using the same.

### 2. Description of the Related Art

Solar cells generate electricity using the photovoltaic effect of a p-n junction which converts photons (e.g., of sunlight) into electricity. In a solar cell, front and rear electrodes may be formed on upper and lower surfaces of a semiconductor wafer or substrate having a p-n junction, respectively. Then, the photovoltaic effect at the p-n junction is induced by light entering the semiconductor wafer and electrons generated by the photovoltaic effect at the p-n junction provide electric current to the outside through the electrodes. The electrodes of the solar cell may be formed on the wafer by applying, patterning, and baking a composition for solar cell electrodes.

### SUMMARY

The embodiments may be realized by providing a composition for solar cell electrodes, the composition including a conductive powder; a glass frit; and an organic vehicle, wherein the glass frit has a reaction index (RI) of about 0.5 to about 1.0, as calculated according to Equation 1:

Reaction index (RI)=Ib/Ia <Equation 1>

wherein, in Equation 1, Ia denotes a maximum peak intensity measured on a specimen at 20.5° to 20.7° (2θ) by XRD analysis, the specimen being obtained by mixing the glass frit with Si₃N₄ powder in a weight ratio of 1:1 to prepare pellets, followed by heat-treatment at 800° C. for 10 minutes, and Ib denotes a maximum peak intensity measured on the specimen at 20.75° to 20.95° (2θ) by XRD analysis.

The glass frit may include tellurium (Te), lithium (Li), zinc (Zn), bismuth (Bi), lead (Pb), sodium (Na), phosphorus (P), silver (Ag), germanium (Ge), gallium (Ga), cerium (Ce), iron (Fe), silicon (Si), tungsten (W), magnesium (Mg), molybdenum (Mo), cesium (Cs), strontium (Sr), titanium (Ti), tin (Sn), indium (In), vanadium (V), barium (Ba), nickel (Ni), copper (Cu), potassium (K), arsenic (As), cobalt (Co), zirconium (Zr), manganese (Mn), aluminum (Al), or boron (B).

The glass frit may include a lead (Pb)-tellurium (Te)-lithium (Li) glass frit, a lead (Pb)-tellurium (Te)-lithium (Li)-zinc (Zn) glass frit, a bismuth (Bi)-tellurium (Te)-lithium (Li) glass frit, or a bismuth (Bi)-tellurium (Te)-lithium (Li)-zinc (Zn) glass frit.

The composition may include about 60 wt % to about 95 wt % of the conductive powder; about 0.1 wt % to about 20 wt % of the glass frit; and about 1 wt % to about 30 wt % of the organic vehicle.

The composition may further include a dispersant, a thixotropic agent, a plasticizer, a viscosity stabilizer, an anti-foaming agent, a pigment, a UV stabilizer, an antioxidant, or a coupling agent.

The embodiments may be realized by providing a solar cell electrode fabricated using the composition for solar cell electrodes according to an embodiment.

### BRIEF DESCRIPTION OF DRAWINGS

Features will be apparent to those of skill in the art by describing in detail exemplary embodiments with reference to the attached drawings in which:

FIG. 1 illustrates a schematic sectional view of a solar cell according to one embodiment.

FIG. 2 illustrates XRD graphs for glass frits of Examples 1 and 2 and Comparative Examples 1 and 2.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or element, it can be directly on the other layer or element, or intervening layers may also be present. Like reference numerals refer to like elements throughout.

As used herein, the singular forms, “a,” “an,” and “the” are intended to include the plural forms as well, unless context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

In addition, unless otherwise stated, a margin of error is considered in analysis of components.

As used herein, the term “metal oxide” may refer to a single metal oxide or a plurality of metal oxides.

Further, “X to Y”, as used herein to represent a range of a certain value means “greater than or equal to X and less than or equal to Y”.

Composition for Solar Cell Electrodes

A composition for solar cell electrodes according to an embodiment may include, e.g., a conductive powder; a glass fit; and an organic vehicle.

Now, each component of the composition for solar cell electrodes will be described in more detail.

Conductive Powder

The conductive powder may impart electrical conductivity to the composition for solar cell electrodes. The composition for solar cell electrodes according to an embodiment may include a metal powder, e.g., silver (Ag) powder or aluminum (Al) powder, as the conductive powder. In an implementation, the conductive powder may be silver powder. The conductive powder may have a, e.g., nanometer or micrometer-scale particle size. In an implementation, the conductive powder may be silver powder having a particle diameter of dozens to several hundred nanometers or having a particle diameter of several to dozens of micrometers. In an implementation, the conductive powder may be a mixture of two or more types of silver powder having different particle sizes.

In an implementation, the conductive powder may have various particle shapes, e.g., a spherical, flake, or amorphous particle shape.

In an implementation, the conductive powder may have an average particle diameter (D50) of about 0.1 μm to about 10 μm, e.g., about 0.5 μm to about 5 μm. Within this range of average particle diameter, the composition may help reduce contact resistance and line resistance of a solar cell. The average particle diameter may be measured using, e.g., a Model 1064D particle size analyzer (CILAS Co., Ltd.) after dispersing the conductive powder in isopropyl alcohol (IPA) at 25° C. for 3 minutes via ultrasonication.

In an implementation, the conductive powder may be present in an amount of about 60% by weight (wt %) to about 95 wt %, e.g., about 70 wt % to about 90 wt %. Within this range, the composition may help improve conversion efficiency of a solar cell and may be easily prepared in paste form.

Glass Frit

The glass frit may form silver crystal grains in an emitter region by etching an anti-reflection layer and melting the conductive powder during a baking process of the composition for solar cell electrodes. Further, the glass frit may help improve adhesion of the conductive powder to a wafer and may be softened to decrease the baking temperature during the baking process.

For example, the glass fit according to an embodiment may have a specific range of reactivity with an anti-reflection film and thus may help minimize serial resistance of a solar cell while improving the fill factor and conversion efficiency of the solar cell. In an implementation, the glass frit may have a reaction index (RI) of, e.g., about 0.5 to about 1.0, as calculated according to Equation 1.

Reaction index (RI)=Ib/Ia <Equation 1>

In Equation 1, Ia denotes a maximum peak intensity measured on a specimen at 20.5° to 20.7° (2θ) by XRD analysis, the specimen being obtained by mixing the glass fit with Si₃N₄ powder in a weight ratio of 1:1 to prepare pellets, followed by heat-treatment at 800° C. for 10 minutes, and Ib denotes a maximum peak intensity measured on the specimen at 20.75° to 20.95° (2θ) by XRD analysis.

Within this range of reaction index, the glass fit may advantageously have good reactivity with the anti-reflection film during the baking process, thereby reducing resistance of a solar cell electrode.

In an implementation, the glass fit may be formed from an oxide or a metal oxide. In an implementation, the oxide or metal oxide may include an oxide of, e.g., tellurium (Te), lithium (Li), zinc (Zn), bismuth (Bi), lead (Pb), sodium (Na), phosphorus (P), germanium (Ge), gallium (Ga), cerium (Ce), iron (Fe), silicon (Si), tungsten (W), magnesium (Mg), molybdenum (Mo), cesium (Cs), strontium (Sr), titanium (Ti), tin (Sn), indium (In), vanadium (V), barium (Ba), nickel (Ni), copper (Cu), potassium (K), arsenic (As), cobalt (Co), zirconium (Zr), manganese (Mn), aluminum (Al), or boron (B).

In an implementation, the glass frit may include, e.g., a lead (Pb)-tellurium (Te)-lithium (Li) glass frit, a lead (Pb)-tellurium (Te)-lithium (Li)-zinc (Zn) glass frit, a bismuth (Bi)-tellurium (Te)-lithium (Li) glass frit, and a bismuth (Bi)-tellurium (Te)-lithium (Li)-zinc (Zn) glass frit. In this case, the glass frit may help improve balance between electrical properties of a solar cell electrode.

In an implementation, the glass frit may be a Te—Bi—Li glass fit including about 10 wt % to about 90 wt % of tellurium (Te), about 0 wt % or more (e.g., greater than 0 wt %) to 30 wt % or less of bismuth (Bi), and about 0 wt % or more (e.g., greater than 0 wt %) to 10 wt % or less of lithium (Li). In an implementation, the Te—Bi—Li-based glass frit has a reaction index falling within the range set forth herein.

In an implementation, the glass fit may be a Te—Bi—Li—Zn-based glass fit including about 10 wt % to about 90 wt % of tellurium (Te), about 0 wt % or more (e.g., greater than 0 wt %) to 30 wt % or less of bismuth (Bi), about 0 wt % or more (e.g., greater than 0 wt %) to 10 wt % or less of lithium (Li), and about 0 wt % or more (e.g., greater than 0 wt %) to 20 wt % or less of zinc (Zn). In an implementation, the Te—Bi—Li—Zn glass fit has a reaction index falling within the range set forth herein.

In an implementation, the glass fit may be a Te—Pb—Li-based glass fit including about 10 wt % to about 90 wt % of tellurium (Te), about 0 wt % or more (e.g., greater than 0 wt %) to 70 wt % or less of lead (Pb), and about 0 wt % or more (e.g., greater than 0 wt %) to 10 wt % or less of lithium (Li). In an implementation, the Te—Pb—Li glass fit may have a reaction index falling within the range set forth herein.

In an implementation, the glass frit may be a Te—Pb—Li—Zn glass frit including about 10 wt % to about 90 wt % of tellurium (Te), about 0 wt % or more (e.g., greater than 0 wt %) to 70 wt % or less of lead (Pb), about 0 wt % or more to 10 wt % or less of lithium (Li), and about 0 wt % or more (e.g., greater than 0 wt %) to 20 wt % or less of zinc (Zn). In an implementation, the Te—Pb—Li—Zn glass fit may have a reaction index falling within the range set forth herein.

The glass fit may be prepared by a suitable method. For example, the glass fit may be prepared by mixing the aforementioned components using a ball mill or a planetary mill, melting the mixture at 900° C. to 1,300° C., and quenching the melted mixture to 25° C., followed by pulverizing the obtained product using a disk mill, a planetary mill, or the like.

In an implementation, the glass fit may be present in an amount of about 0.1 wt % to about 20 wt %, e.g., about 0.5 wt % to about 10 wt %, in the composition for solar cell electrodes. Within this range, the glass frit may help secure stability of a p-n junction under various sheet resistances, minimize resistance, and ultimately improve efficiency of a solar cell.

Organic Vehicle

The organic vehicle may impart suitable viscosity and rheological characteristics for printing to the composition for solar cell electrodes through mechanical mixing with inorganic components of the composition.

In an implementation, the organic vehicle may be a suitable organic vehicle used in a composition for solar cell electrodes and may include a binder resin, a solvent, or the like.

The binder resin may be selected from acrylate resins or cellulose resins. Ethyl cellulose may be used as the binder resin. In an implementation, the binder resin may be of ethyl hydroxyethyl cellulose, nitrocellulose, blends of ethyl cellulose and phenol resins, alkyd resins, phenol resins, acrylate ester resins, xylene resins, polybutane resins, polyester resins, urea resins, melamine resins, vinyl acetate resins, wood rosin, polymethacrylates of alcohols, and the like.

In an implementation, the solvent may be one or more of, e.g., hexane, toluene, ethyl cellosolve, cyclohexanone, butyl cellosolve, butyl carbitol (diethylene glycol monobutyl ether), dibutyl carbitol (diethylene glycol dibutyl ether), butyl carbitol acetate (diethylene glycol monobutyl ether acetate), propylene glycol monomethyl ether, hexylene glycol, terpineol, methylethylketone, benzylalcohol, γ-butyrolactone, or ethyl lactate. These may be used alone or as a mixture thereof.

In an implementation, the organic vehicle may be present in an amount of about 1 wt % to about 30 wt % in the composition for solar cell electrodes. Within this range, the organic vehicle may help provide sufficient adhesive strength and good printability to the composition.

Additive

In an implementation, the composition for solar cell electrodes may further include a suitable additive to, e.g., enhance fluidity, process properties and stability. In an implementation, the additive may include a dispersant, a thixotropic agent, a plasticizer, a viscosity stabilizer, an anti-foaming agent, a pigment, a UV stabilizer, an antioxidant, a coupling agent, or the like. These may be used alone or as mixtures thereof. In an implementation, the additive may be present in an amount of, e.g., about 0.1 wt % to about 5 wt % based on the total weight of the composition for solar cell electrodes.

Solar Cell Electrode and Solar Cell Including the Same

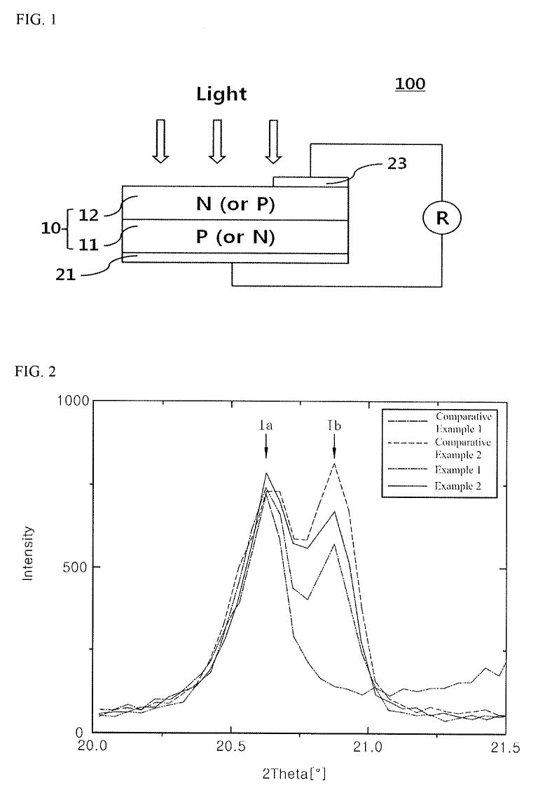

Other embodiments relate to an electrode formed of the composition for solar cell electrodes and a solar cell including the same. FIG. 1 illustrates a solar cell in accordance with one embodiment.

Referring to FIG. 1, a solar cell 100 according to this embodiment may include a substrate 10, a front electrode 23 formed on a front surface of the substrate 10, and a rear electrode 21 formed on a back surface of the substrate 10.

In an implementation, the substrate 10 may be a substrate with a p-n junction formed thereon. For example, the substrate 10 may include a semiconductor substrate 11 and an emitter 12. In an implementation, the substrate 10 may be a substrate prepared by doping one surface of a p-type semiconductor substrate 11 with an n-type dopant to form an n-type emitter 12. In an implementation, the substrate 10 may be a substrate prepared by doping one surface of an n-type semiconductor substrate 11 with a p-type dopant to form a p-type emitter 12. Here, the semiconductor substrate 11 may be either a p-type substrate or an n-type substrate. The p-type substrate may be a semiconductor substrate 11 doped with a p-type dopant, and the n-type substrate may be a semiconductor substrate 11 doped with an n-type dopant.

In description of the substrate 10, the semiconductor substrate 11, and the like, a surface of such a substrate through which light enters the substrate is referred to as a front surface (light receiving surface). In addition, a surface of the substrate opposite the front surface is referred to as a back surface.

In an implementation, the semiconductor substrate 11 may be formed of crystalline silicon or a compound semiconductor. For example, the crystalline silicon may be monocrystalline or polycrystalline. As the crystalline silicon, e.g., a silicon wafer may be used.

In an implementation, the p-type dopant may be a material including a group III element, e.g., boron, aluminum, or gallium. In an implementation, the n-type dopant may be a material including a group V element, e.g., phosphorus, arsenic or antimony.

The front electrode 23 and/or the rear electrode 21 may be fabricated using the composition for solar cell electrodes according to an embodiment. For example, the front electrode 23 may be fabricated using the composition including silver powder as the conductive powder, and the rear electrode 21 may be fabricated using the composition including aluminum powder as the conductive powder. The front electrode 23 may be formed by printing the composition for solar cell electrodes onto the emitter 12, followed by baking, and the rear electrode 21 may be formed by applying the composition for solar cell electrodes to the back surface of the semiconductor substrate 11, followed by baking.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### Example 1

As an organic binder, 3.0 wt % of ethyl cellulose (STD4, Dow Chemical Company) was sufficiently dissolved in 6.5 wt % of Butyl Carbitol at 60° C., and then 87.5 wt % of spherical silver powder (AG-4-8, Dowa Hightech Co., Ltd.) having an average particle diameter of 2.0 μm, 2.5 wt % of a Bi—Te—Li—Zn glass fit having an RI of 0.77 (GCT-1, Asahi Chemical Co., Ltd.), 0.2 wt % of a dispersant (BYK102, BYK-chemie), and 0.3 wt % of a thixotropic agent (Thixatrol ST, Elementis Co., Ltd.) were added to the binder solution, followed by mixing and kneading in a 3-roll kneader, thereby preparing a composition for solar cell electrodes.

### Example 2

A composition for solar cell electrodes was prepared in the same manner as in Example 1 except that a Bi—Te—Li—Zn glass fit having an RI of 0.85 (MTG-33, Asahi Chemical Co., Ltd.) was used.

### Comparative Example 1

A composition for solar cell electrodes was prepared in the same manner as in Example 1 except that a Pb—Te—Li glass frit having an RI of 0.20 (TDR-1, Asahi Chemical Co., Ltd.) was used.

### Comparative Example 2

A composition for solar cell electrodes was prepared in the same manner as in Example 1 except that a Bi—Te—Li—Zn glass frit having an RI of 1.12 (ABT-1, Asahi Chemical Co., Ltd.) was used.

### Comparative Example 3

A composition for solar cell electrodes was prepared in the same manner as in Example 1 except that a Bi—Te—Li—Zn glass frit having an RI of 0.4 (CTB-6, PARTICLOGY Co., Ltd.) was used.

Property Evaluation

(1) Serial resistance (Rs, mΩ) and open-circuit voltage (Voc, mV): Each of the compositions for solar cell electrodes prepared in the Examples and Comparative Examples was deposited onto a front surface of a wafer by screen printing in a predetermined pattern, followed by drying in an IR drying furnace. A cell formed according to this procedure was subjected to baking at 600° C. to 900° C. for 60 to 210 seconds in a belt-type baking furnace, and then evaluated as to serial resistance (Rs) and open-circuit voltage (Voc) using a solar cell efficiency tester CT-801 (Pasan Co., Ltd.). Results are shown in Table 1.

(2) Fill Factor (%) and Efficiency (%): Each of the compositions for solar cell electrodes prepared in the Examples and Comparative Examples was deposited onto a front surface of a wafer by screen printing in a predetermined pattern, followed by drying in an IR drying furnace. Then, an aluminum paste was printed onto a back surface of the wafer and dried in the same manner as above. A cell formed according to this procedure was subjected to baking at 400° C. to 900° C. for 30 to 180 seconds in a belt-type baking furnace, and then evaluated as to fill factor (FF, %) and conversion efficiency (Eff., %) using a solar cell efficiency tester CT-801 (Pasan Co., Ltd.). Results are shown in Table 1.

TABLE 1

| | Reaction | | | | |
|---|---|---|---|---|---|
| | index of | Serial | | | |
| | glass | resistance | Open-circuit | | |
| | frit (RI) | (mΩ) | voltage (mV) | FF (%) | Eff. (%) |
| Example 1 | 0.77 | 2.64 | 638.4 | 79.534 | 19.695 |
| Example 2 | 0.85 | 2.62 | 638.3 | 79.578 | 19.723 |
| Comparative | 0.2 | 2.8 | 639.4 | 79.216 | 19.662 |
| Example 1 | | | | | |
| Comparative | 1.12 | 2.73 | 637.4 | 79.294 | 19.634 |
| Example 2 | | | | | |
| Comparative | 0.4 | 2.74 | 637.8 | 79.263 | 19.657 |
| Example 3 | | | | | |

As shown in Table 1, it may be seen that the solar cell electrodes fabricated using the compositions for solar cell electrodes, each including the glass frit having a reaction index (RI) falling within the range set forth herein, exhibited good (optimal) reactivity between an anti-reflection film and the glass frit, thereby minimizing serial resistance while providing good fill factor and conversion efficiency.

By way of summation and review, as the composition for solar cell electrodes, a conductive paste composition including a conductive powder, a glass fit, and an organic vehicle may be used. The glass frit may melt an anti-reflection film on a semiconductor wafer, thereby establishing electrical contact between the conductive powder and the wafer.

For example, reactivity of the glass frit with the anti-reflection film may have an influence on electrical characteristics of a solar cell, such as serial resistance (Rs) and open-circuit voltage (Voc) of an electrode, and thus may be a consideration with a view toward improving the fill factor and conversion efficiency of the solar cell.

A composition for solar cell electrodes which can improve electrical characteristics of a solar cell electrode may be desirable.

The embodiments may provide a composition for solar cell electrodes capable of minimizing resistance.

The embodiments may provide a composition for solar cell electrodes providing good fill factor and conversion efficiency.

### LIST OF REFERENCE NUMERALS

10: substrate
11: semiconductor substrate
12: emitter
21: rear electrode
23: front electrode

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A composition for solar cell electrodes, the composition comprising:
a conductive powder;
a glass frit; and
an organic vehicle,
wherein the glass frit has a reaction index (RI) of about 0.5 to about 1.0, as calculated according to Equation 1:
Reaction index (RI)=Ib/Ia <Equation 1>
wherein, in Equation 1,
Ia denotes a maximum peak intensity measured on a specimen at 20.5° to 20.7° (2θ) by XRD analysis, the specimen being obtained by mixing the glass frit with Si₃N₄ powder in a weight ratio of 1:1 to prepare pellets, followed by heat-treatment at 800° C. for 10 minutes, and
Ib denotes a maximum peak intensity measured on the specimen at 20.75° to 20.95° (2θ) by XRD analysis.

2. The composition as claimed in claim 1, wherein the glass frit includes tellurium (Te), lithium (Li), zinc (Zn), bismuth (Bi), lead (Pb), sodium (Na), phosphorus (P), silver (Ag), germanium (Ge), gallium (Ga), cerium (Ce), iron (Fe), silicon (Si), tungsten (W), magnesium (Mg), molybdenum (Mo), cesium (Cs), strontium (Sr), titanium (Ti), tin (Sn), indium (In), vanadium (V), barium (Ba), nickel (Ni), copper (Cu), potassium (K), arsenic (As), cobalt (Co), zirconium (Zr), manganese (Mn), aluminum (Al), or boron (B).

3. The composition as claimed in claim 1, wherein the glass frit includes a lead (Pb)-tellurium (Te)-lithium (Li) glass frit, a lead (Pb)-tellurium (Te)-lithium (Li)-zinc (Zn) glass frit, a bismuth (Bi)-tellurium (Te)-lithium (Li) glass frit, or a bismuth (Bi)-tellurium (Te)-lithium (Li)-zinc (Zn) glass frit.

4. The composition as claimed in claim 1, wherein the composition includes:
about 60 wt % to about 95 wt % of the conductive powder;
about 0.1 wt % to about 20 wt % of the glass fit; and
about 1 wt % to about 30 wt % of the organic vehicle.

5. The composition as claimed in claim 1, further comprising a dispersant, a thixotropic agent, a plasticizer, a viscosity stabilizer, an anti-foaming agent, a pigment, a UV stabilizer, an antioxidant, or a coupling agent.

6. A solar cell electrode fabricated using the composition for solar cell electrodes as claimed in claim 1.
